(19) United States
(12) Patent Application Publication
(10) Pub. No.: US 2025/0079173 A1
(43) Pub. Date: Mar. 6, 2025

(54) PLASMA PROCESSING METHOD AND PLASMA PROCESSING SYSTEM

(71) Applicant: Tokyo Electron Limited, Tokyo (JP)

(72) Inventors: Daisuke YOSHIKOSHI, Miyagi (JP); Yusuke SHIMIZU, Miyagi (JP); Shigeru TAHARA, Miyagi (JP)

(21) Appl. No.: 18/951,442

(22) Filed: Nov. 18, 2024

Related U.S. Application Data
(63) Continuation of application No. PCT/JP2023/017723, filed on May 11, 2023.

(30) Foreign Application Priority Data
May 19, 2022 (JP) 2022-082114

(51) Int. Cl. H01L 21/033; H01L 21/311; H01L 21/67

(52) U.S. Cl. CPC H01L 21/0337; H01L 21/31116; H01L 21/31144; H01L 21/67069

(57) ABSTRACT

Provided is a plasma processing method performed with a plasma processing apparatus including a chamber. This method includes: (a) preparing a substrate on a substrate support in the chamber, the substrate including an etching target film and a metal-containing film provided on the etching target film, the metal-containing film including an exposed first region and an unexposed second region; (b) reforming the metal-containing film using a first plasma formed from a first processing gas, the first processing gas including either a fluorine-containing gas or an oxygen-containing gas; and (c) selectively removing the first region of the reformed metal-containing film with respect to the second region using a second plasma formed from a second processing gas.

### CROSS-REFERENCE TO RELATED APPLICATION

The present application claims priority under 35 U.S.C. § 119 to Japanese Patent Application No. 2022-082114 filed on May 19, 2022 and PCT Application No. PCT/JP2023/017723 filed on May 11, 2023, the entire contents of which are incorporated herein by reference.

### BACKGROUND

### Field

An exemplary embodiment of the present invention relates to a plasma processing method and a plasma processing system.

### Description of Related Art

US 2017/0243744 A discloses a technique for trimming a non-organic film.

### SUMMARY

In an exemplary embodiment of the present disclosure, there is provided a plasma processing method performed with a plasma processing apparatus including a chamber. The method includes: (a) preparing a substrate on a substrate support in the chamber, the substrate including an etching target film and a metal-containing film provided on the etching target film, the metal-containing film including an exposed first region and an unexposed second region; (b) reforming the metal-containing film using a first plasma formed from a first processing gas, the first processing gas including either a fluorine-containing gas or an oxygen-containing gas; and (c) selectively removing the first region of the reformed metal-containing film with respect to the second region using a second plasma formed from a second processing gas.

### BRIEF DESCRIPTION OF DRAWINGS

FIG. 1 is a diagram schematically illustrating an exemplary plasma processing system.

FIG. 2 is a flowchart illustrating an exemplary plasma processing method.

FIG. 3 is a diagram schematically illustrating an example of a cross-sectional structure of a substrate W provided in Step ST1.

FIG. 4 is a diagram schematically illustrating an example of a cross-sectional structure of the substrate W after a process in Step ST2.

FIG. 5 is a diagram schematically illustrating an example of a cross-sectional structure of the substrate W after a process in Step ST3.

FIG. 6 is a diagram schematically illustrating an example of a cross-sectional structure of the substrate W after a process in Step ST4.

### DETAILED DESCRIPTION

Hereinafter, each embodiment of the present disclosure will be described.

In an exemplary embodiment, there is provided a plasma processing method performed with a plasma processing apparatus including a chamber. The method includes: (a) preparing a substrate on a substrate support in the chamber, the substrate including an etching target film and a metal-containing film provided on the etching target film, the metal-containing film including an exposed first region and an unexposed second region; (b) reforming the metal-containing film using a first plasma formed from a first processing gas, the first processing gas including either a fluorine-containing gas or an oxygen-containing gas; and (c) selectively removing the first region of the reformed metal-containing film with respect to the second region using a second plasma formed from a second processing gas.

In an exemplary embodiment, by the reforming in (b), etching resistance of the second region to the second plasma is higher than etching resistance of the first region to the second plasma.

In an exemplary embodiment, (c) includes removing the first region such that the etching target film is exposed.

In an exemplary embodiment, the metal-containing film includes tin or titanium.

In an exemplary embodiment, the metal-containing film includes an organic substance.

In an exemplary embodiment, the first processing gas includes at least one selected from the group consisting of fluorocarbon gas, hydrofluorocarbon gas, NF₃ gas, and SF₆ gas.

In an exemplary embodiment, the second processing gas further includes a chlorine-containing gas.

In an exemplary embodiment, the chlorine-containing gas is BCl₃ gas or Cl₂ gas.

In an exemplary embodiment, the first processing gas includes at least one selected from the group consisting of O₂ gas, CO gas, and CO₂ gas.

In an exemplary embodiment, the first processing gas further includes a chlorine-containing gas.

In an exemplary embodiment, the chlorine-containing gas is at least one selected from the group consisting of Cl₂ gas, BCI₃ gas, and SiCl₄ gas.

In an exemplary embodiment, (c) includes alternately repeating (i) formation of the second plasma using a gas including a hydrogen-containing gas and a nitrogen-containing gas as the second processing gas and (ii) formation of the second plasma using a gas including a chlorine-containing gas as the second processing gas.

In an exemplary embodiment, the etching target film is a Si-containing film or a carbon-containing film.

In an exemplary embodiment, the plasma processing method further includes (d) etching the etching target film, using the metal-containing film as a mask, after (c).

In an exemplary embodiment, (a) to (d) are performed in the same chamber.

In an exemplary embodiment, the metal-containing film includes a metal-containing photoresist film, the first region is an exposed region of the metal-containing photoresist film, and the second region is an unexposed region of the metal-containing photoresist film.

In an exemplary embodiment, the first region is exposed to EUV.

In an exemplary embodiment, there is provided a plasma processing system including a chamber, a substrate support configured to be disposed in the chamber; and a controller. The controller is configured to cause: (a) preparing a substrate on a substrate support in the chamber, the substrate including an etching target film and a metal-containing film provided on the etching target film, the metal-containing film including an exposed first region and an unexposed second region; (b) reforming the metal-containing film using a first plasma formed from a first processing gas, the first processing gas including either a fluorine-containing gas or an oxygen-containing gas; and (c) selectively removing the first region of the reformed metal-containing film with respect to the second region using a second plasma formed from a second processing gas.

Hereinafter, each embodiment of the present disclosure will be described in detail with reference to the drawings. Further, in each drawing, the same or similar elements are denoted by the same reference numerals, and a repeated description of the elements will be omitted. Unless otherwise specified, positional relationships, such as up, down, left, and right sides, will be described based on positional relationships illustrated in the drawings. A dimensional ratio in the drawings does not indicate an actual ratio, and the actual ratio is not limited to the ratio illustrated in the drawings.

### <Example of Configuration of Plasma Processing System>

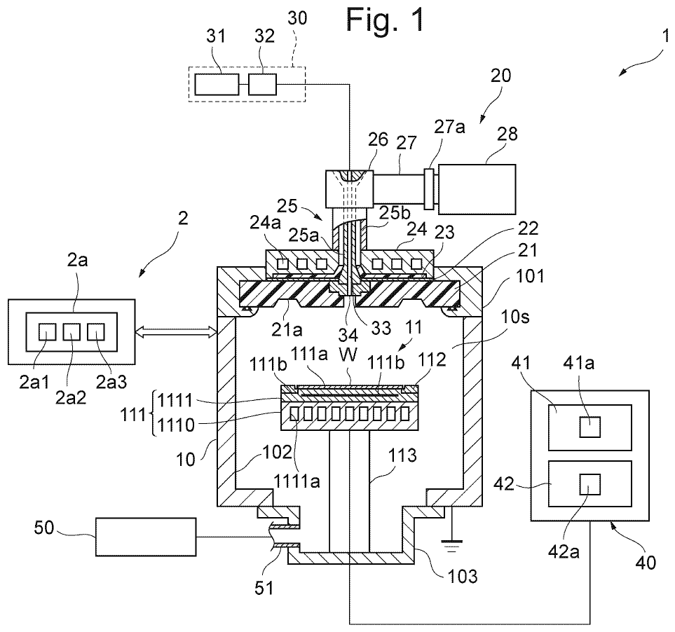

Hereinafter, an example of a configuration of a plasma processing system will be described. FIG. 1 is a diagram schematically illustrating an exemplary plasma processing system.

The plasma processing system includes a plasma processing apparatus 1 using a microwave plasma source and a controller 2. The plasma processing apparatus 1 includes a plasma processing chamber 10, a microwave plasma source 20, a gas supply 30, a bias power supply 40, and an exhaust system 50. In addition, the plasma processing apparatus 1 includes a substrate support 11 and a gas introducer. The substrate support 11 is disposed in the plasma processing chamber 10. The plasma processing chamber 10 has a plasma processing space 10s defined by a ring-shaped support 101, a side wall 102 of the plasma processing chamber 10, an exhaust chamber 103, and the substrate support 11. The plasma processing chamber 10 has at least one gas supply port for supplying at least one processing gas to the plasma processing space 10s and at least one gas exhaust port for exhausting a gas from the plasma processing space. The plasma processing chamber 10 is grounded.

The substrate support 11 includes a main body 111, a ring assembly 112, and a support member 113. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 such that the ring assembly 112 surrounds the substrate W on the central region 111a of the main body 111. Therefore, the central region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. In addition, another member, such as an annular electrostatic chuck or an annular insulating member, that surrounds the electrostatic chuck 1111 may have the annular region 111b. In this case, the ring assembly 112 may be disposed on the annular electrostatic chuck or the annular insulating member or may be disposed on both the electrostatic chuck 1111 and the annular insulating member. In addition, at least one radio frequency (RF)/direct current (DC) electrode coupled to an RF power supply 41 and/or a DC power supply 42, which will be described below, may be disposed in the ceramic member 1111a. In this case, the at least one RF/DC electrode functions as the bias electrode. In addition, the conductive member of the base 1110 and the at least one RF/DC electrode may function as a plurality of bias electrodes. Further, the electrostatic electrode 1111b may function as the bias electrode. Therefore, the substrate support 11 includes at least one bias electrode.

The ring assembly 112 includes one or a plurality of annular members. In an embodiment, one or a plurality of annular members includes one or a plurality of edge rings and at least one cover ring. The edge ring is formed from a conductive material or an insulating material, and the cover ring is formed from an insulating material.

The support member 113 is a member that supports the main body 111. The support member 113 may have a cylindrical shape that extends upward from a center of a bottom of the exhaust chamber 103. The support member 113 is formed from a ceramic material such as AlN.

In addition, the substrate support 11 may include a temperature control module that is configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In an embodiment, the flow path 1110a is formed in the base 1110, and one or a plurality of heaters is disposed in the ceramic member 1111a of the electrostatic chuck 1111. Further, the substrate support 11 may include a heat transfer gas supply configured to supply a heat transfer gas to a gap between a back surface of the substrate W and the central region 111a.

The microwave plasma source 20 is supported by the support 101. The microwave plasma source 20 includes a microwave transmission plate 21, a planar slot antenna 22, a slow wave material 23, a cooling jacket 24, a coaxial waveguide 25, a mode converter 26, a waveguide 27, and a microwave generator 28.

The microwave transmission plate 21 is airtightly configured on the support, with a sealing member interposed therebetween. Therefore, the plasma processing chamber 10 is kept airtight. The microwave transmission plate 21 may be, for example, a disk-shaped dielectric that is formed from quartz or ceramics such as Al₂O₃.

The planar slot antenna 22 has a plurality of slots, has a disk shape corresponding to the microwave transmission plate 21, and is configured such that the planar slot antenna 22 is in close contact with the microwave transmission plate 21. The planar slot antenna 22 may be locked to an upper end of the side wall 102 of the plasma processing chamber 10.

The planar slot antenna 22 may be, for example, a disk-shaped conductor. In addition, the planar slot antenna 22 includes, for example, a copper plate or an aluminum plate having a surface plated with silver or gold, and a plurality of slots for radiating microwaves is formed in a predetermined pattern in the planar slot antenna 22 such that the plurality of slots penetrates the planar slot antenna 22. The pattern of the slots may be set such that the microwaves are uniformly radiated to the substrate W. A pattern in which two slots disposed in a T-shape form a pair and a plurality of pairs of slots is concentrically disposed can be given as an example of the pattern of the slots. A length of the slot and an arrangement interval of the slots are determined according to an effective wavelength (Ag) of the microwave. For example, the slots may be disposed such that an interval between the slots is Ag/4, Ag/2, or Ag. In addition, the slot may have other shapes such as a circular shape and an arc shape. Further, the disposition form of the slots is not particularly limited, and the slots can be disposed, for example, in a spiral shape or a radial shape in addition to the concentric circular shape. In addition, the planar slot antenna 22 may be disposed to be spaced apart from the microwave transmission plate 21.

The slow wave material 23 is provided to be in close contact with an upper surface of the planar slot antenna 22. The slow wave material 23 may be a dielectric having a larger dielectric constant than vacuum. The slow wave material 23 may be formed from, for example, quartz, ceramics (Al₂O₃), polytetrafluoroethylene, or a resin such as polyimide. The slow wave material 23 has a function of making the wavelength of the microwave shorter than a wavelength in a vacuum to adjust a phase of the microwave. In addition, the slow wave material 23 may be disposed to be spaced apart from the planar slot antenna 22. The thicknesses of the microwave transmission plate 21 and the slow wave material 23 are adjusted such that an equivalent circuit formed by the microwave transmission plate 21, the planar slot antenna 22, and the slow wave material 23 satisfies a resonance condition. The thickness of the slow wave material 23 can be adjusted to adjust the phase of the microwave. The thickness of the slow wave material 23 is adjusted such that a joint between the planar slot antenna 22 and the slow wave material 23 is an “antinode” of a standing wave. As a result, the reflection of the microwave is minimized, and the radiation energy of the microwave is maximized. In addition, the microwave transmission plate 21 and the slow wave material 23 may be made of the same material to suppress the interface reflection of the microwave.

The cooling jacket 24 is provided on the upper surface of the plasma processing chamber 10 such that the cooling jacket 24 covers the planar slot antenna 22 and the slow wave material 23. The cooling jacket 24 may be, for example, a thermal conductor that is made of a metal material such as aluminum, stainless steel, or copper. A cooling water flow path 24a is provided in the cooling jacket 24. Cooling water flows through the cooling water flow path 24a to cool the microwave transmission plate 21, the planar slot antenna 22, and the slow wave material 23.

The coaxial waveguide 25 is inserted from an upper side of an opening portion provided at the center of the cooling jacket 24 toward the microwave transmission plate 21. An inner conductor 25a having a hollow rod shape and an outer conductor 25b having a cylindrical shape are concentrically disposed in the coaxial waveguide 25. An upper end of the coaxial waveguide 25 is connected to the mode converter 26. A lower end of the inner conductor 25a is connected to the planar slot antenna 22. A lower end of the outer conductor 25b is connected to the slow wave material 23.

The mode converter 26 is configured such that the mode converter 26 is connected to the microwave generator 28 through the waveguide 27 that extends horizontally and has a rectangular shape in a cross-sectional view. The mode converter 26 has a function of converting a vibration mode of the microwave.

The waveguide 27 is configured such that one end is connected to the mode converter 26 and the other end is connected to the microwave generator 28. A matching circuit 27a is provided in the waveguide 27.

The microwave generator 28 generates, for example, a microwave having a frequency of 2.45 GHZ. The generated microwave propagates through the waveguide 27, the vibration mode is converted from a TE mode to a TEM mode by the mode converter 26, and the microwave propagates toward the slow wave material 23 through the coaxial waveguide 25. The microwave spreads radially outward from the inside of the slow wave material 23 in a radial direction and is radiated from the slots of the planar slot antenna 22. The radiated microwave is transmitted through the microwave transmission plate 21 to generate an electric field in the plasma processing space 10s immediately below the microwave transmission plate 21 such that microwave plasma is formed from the processing gas in the plasma processing space 10s. An annular recessed portion 21a that is recessed in a tapered shape may be formed in a lower surface of the microwave transmission plate 21, which makes it possible to efficiently form the microwave plasma.

In addition to 2.45 GHZ, various frequencies, such as 8.35 GHZ, 1.98 GHz, 860 MHZ, and 915 MHz, may be used as the frequency of the microwave. Further, for example, the power of the microwave may be equal to or greater than 2,000 W and equal to or less than 5,000 W, and power density may be equal to or greater than 2.8 W/cm² and equal to or less than 7.1 W/cm².

The gas supply 30 may include at least one gas source 31 and at least one flow rate controller 32. In an embodiment, the gas supply 30 is configured to supply at least one processing gas from the gas source 31 corresponding to each processing gas to the gas introducer through the flow rate controller 32 corresponding to each processing gas. Each flow rate controller 32 may include, for example, a mass flow controller or a flow rate controller of a pressure control type. Further, the gas supply 30 may include one or more flow rate modulation devices that modulate or pulse the flow rate of at least one processing gas.

The gas introducer is configured to introduce at least one processing gas from the gas supply 30 into the plasma processing space 10s. In an embodiment, the gas introducer includes a gas flow path 33 that is formed in the mode converter 26 and the inner conductor 25a of the coaxial waveguide 25, and a gas supply port 34 at a distal end of the gas flow path is open to the plasma processing space 10s, for example, in the central portion of the microwave transmission plate 21. The processing gas introduced from the gas supply 30 into the gas introducer passes through the gas flow path 33 and is supplied from the gas supply port 34 into the plasma processing space 10s. In addition, the gas introducer may include one or a plurality of side gas injectors (SGIs) that is attached to one or a plurality of opening portions formed in the side wall 102 in addition to or instead of the gas flow path 33.

The bias power supply 40 includes the RF power supply 41 that is coupled to the plasma processing chamber 10 through at least one impedance matching circuit. The RF power supply 41 is configured to supply an RF signal (RF power) to the bias electrode. Therefore, at least one bias RF signal is supplied to the bias electrode to form a bias potential on the substrate W, and ions in the formed plasma can be attracted to the substrate W.

In an embodiment, the RF power supply 41 includes an RF generator 41a. The RF generator 41a is configured to be coupled to at least one bias electrode through at least one impedance matching circuit and to generate the bias RF signal (bias RF power). In an embodiment, the bias RF signal has a frequency in a range of 100 KHz to 60 MHZ. In an embodiment, the RF generator 41a may be configured to generate a plurality of bias RF signals having different frequencies. The generated one or plurality of bias RF signals are supplied to at least one bias electrode. In addition, in various embodiments, the bias RF signal may be pulsed.

Further, the bias power supply 40 may include the DC power supply 42 that is coupled to the plasma processing chamber 10. The DC power supply 42 includes a bias DC generator 42a. In an embodiment, the bias DC generator 42a is configured to be connected to at least one bias electrode and to generate a bias DC signal. The generated bias DC signal is applied to at least one bias electrode.

In various embodiments, the bias DC signal may be pulsed. In this case, a sequence of voltage pulses is applied to at least one bias electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the bias DC generator 42a and at least one bias electrode. Therefore, the bias DC generator 42a and the waveform generator constitute a voltage pulse generator. The voltage pulse may have a positive polarity or a negative polarity. In addition, the sequence of voltage pulses may include one or a plurality of positive voltage pulses and one or a plurality of negative voltage pulses in one period. Further, the bias DC generator 42a may be provided in addition to the RF power supply 41.

The exhaust system 50 may be connected to, for example, a gas exhaust port 51 provided in the exhaust chamber 103. The exhaust system 50 may include a pressure adjustment valve and a vacuum pump. The pressure in the plasma processing space 10s is adjusted by the pressure adjustment valve. The vacuum pump may include a turbomolecular pump, a dry pump, or a combination thereof.

The controller 2 processes computer-executable instructions that cause the plasma processing apparatus 1 to execute various steps described in the present disclosure. The controller 2 may be configured to control each element of the plasma processing apparatus 1 such that various steps described here are executed. In an embodiment, a portion or all of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may be configured to read out a program from the storage 2a2 and to execute the read-out program to perform various control operations. This program may be stored in the storage 2a2 in advance or may be acquired through a medium as necessary. The acquired program is stored in the storage 2a2, and the processor 2a1 reads out the program from the storage 2a2 and executes the program. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### <Example of Plasma Processing Method>

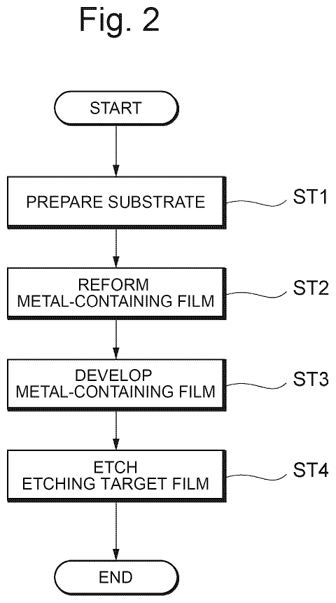

FIG. 2 is a flowchart illustrating a plasma processing method (hereinafter, also referred to as “the present processing method”) according to an exemplary embodiment. As illustrated in FIG. 2, the present processing method includes Step ST1 of preparing a substrate, Step ST2 of reforming a metal-containing film (hereinafter, also referred to as a “reforming process”), and Step ST3 of developing the metal-containing film (hereinafter, also referred to as a “development process”). The present processing method may further include Step ST4 of etching an etching target film. The process in each step may be executed by the plasma processing system illustrated in FIG. 1. Hereinafter, a case where the controller 2 controls each unit of the plasma processing apparatus 1 such that the present processing method is executed on the substrate W will be described as an example.

### (Step ST1: Preparation of Substrate)

In Step ST1, the substrate W is prepared in the plasma processing chamber 10s of the plasma processing apparatus 1. The substrate W is disposed on the central region 111a of the substrate support 11. Then, the substrate W is held on the substrate support 11 by the electrostatic chuck 1111.

After the substrate W is disposed on the central region 111a of the substrate support 11, the temperature of the substrate support 11 may be adjusted to a set temperature by the temperature control module. The set temperature may be, for example, a temperature of 60° C. or lower (in an example, normal temperature). In an example, adjusting or maintaining the temperature of the substrate support 11 includes adjusting or maintaining the temperature of the heat transfer fluid flowing through the flow path 1110a to the set temperature or a temperature different from the set temperature. In an example, adjusting or maintaining the temperature of the substrate support 11 includes controlling the pressure of a heat transfer gas (for example, He) between the electrostatic chuck 1111 and the back surface of the substrate W. The heat transfer fluid may start to flow through the flow path 1110a before or after the substrate W is placed on the substrate support 11 or at the same time as the substrate W is placed on the substrate support 11. In addition, in the present processing method, the temperature of the substrate support 11 may be adjusted to the set temperature before Step ST1. That is, the substrate W may be prepared on the substrate support 11 after the temperature of the substrate support 11 is adjusted to the set temperature. In the subsequent steps of the present processing method, the temperature of the substrate support 11 is maintained at the set temperature adjusted in Step ST1.

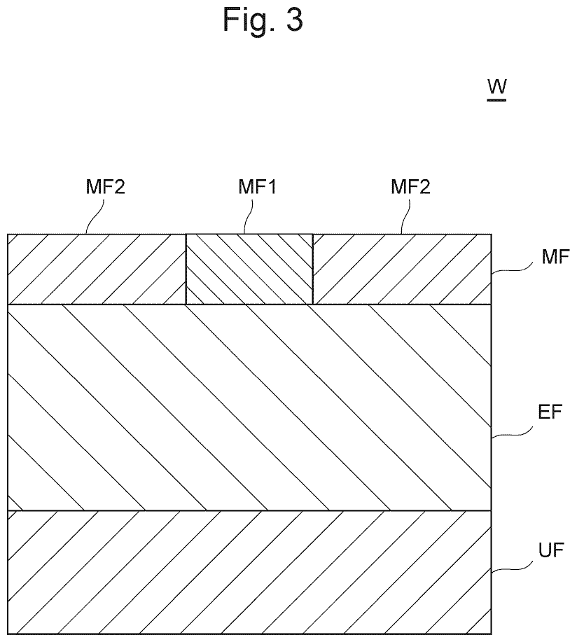

FIG. 3 is a diagram illustrating an example of a cross-sectional structure of the substrate W prepared in Step ST1. In the substrate W, a film EF to be etched and a metal-containing film MF are stacked in this order on an underlying film UF. The substrate W may be used for manufacturing a semiconductor device. Examples of the semiconductor device include semiconductor memory devices such as a DRAM and a 3D-NAND flash memory.

The underlying film UF is, for example, a silicon wafer or a carbon-containing film, a dielectric film, a metal film, a semiconductor film, or the like, formed on the silicon wafer. The underlying film UF may be configured by stacking a plurality of films.

The film EF to be etched is a film different from the underlying film UF. The film EF to be etched may be, for example, a carbon-containing film, a dielectric film, a semiconductor film, or a metal film. The film EF to be etched may be configured by one film or may be configured by stacking a plurality of films. For example, the film EF to be etched may be configured by stacking one or a plurality of films such as a silicon-containing film, a carbon-containing film, a spin-on-glass (SOG) film, and a Si-containing antireflective coating (SiARC).

Each of the underlying film UF and the film EF to be etched constituting the substrate W may be formed by a CVD method, an ALD method, a spin coating method, or the like. The underlying film UF and the film EF to be etched may be flat films or films having unevenness.

The metal-containing film MF is formed on an upper surface of the film EF to be etched. The metal-containing film MF is a film containing metal and has an exposed first region MF1 and an unexposed second region MF2.

The metal-containing film MF is a “negative” film. That is, the etching resistance of the exposed first region MF1 to the plasma used in the development process is higher than the etching resistance of the unexposed second region MF2. For example, in a case where the metal-containing film MF is exposed to a second plasma used in the development process in Step ST3, the unexposed second region MF2 is removed, and the exposed first region MF1 remains.

The metal-containing film MF may be a film containing tin or titanium. In an example, the metal-containing film MF may include tin oxide. The metal-containing film MF may include an organic substance. In the metal-containing film MF, the first region MF1 and the second region MF2 may contain different components and/or may have different content ratios of the components. In an example, the film constituting the first region MF1 may include oxygen, carbon, and tin. In an example, the film constituting the second region MF2 may include carbon and tin. The film constituting the first region MF1 and/or the second region MF2 may further include silicon.

The metal-containing film MF may be formed by lithography. For example, first, a photoresist film containing metal is formed on the film EF to be etched. Then, the photoresist film is selectively irradiated with light (for example, an EUV excimer laser or the like) through an exposure mask. As a result, the metal-containing film MF having the exposed first region MF1 and the unexposed second region MF2 is formed. The first region MF1 is a region that corresponds to an opening provided in the exposure mask. The second region MF2 is a region that corresponds to a pattern provided in the exposure mask.

At least some of the processes of forming each configuration of the substrate W may be performed in the plasma processing space 10s. In addition, after all or some of the configurations of the substrate W are formed by an apparatus or a chamber outside the plasma processing apparatus 1, the substrate W may be provided in the plasma processing space 10s.

### (Step ST2: Reforming of Metal-Containing Film)

In Step ST2, the metal-containing film MF is reformed. First, the first processing gas is supplied from the gas supply 30 into the plasma processing chamber 10s. The first processing gas includes either a fluorine-containing gas or an oxygen-containing gas. Then, the microwave is radiated from the microwave plasma source 20 into the plasma processing chamber 10s. As a result, the first plasma including an active species of fluorine or oxygen is formed from the first processing gas. The metal-containing film MF is exposed to the first plasma to be reformed. The reforming may include fluorination or oxidation of the metal-containing film MF. The reforming may include a change in at least some of the components contained in the metal-containing film MF and/or a change in the ratio of the components. The reforming may include a case where a portion or all of the metal-containing film MF is hardened or a case where a portion of the metal-containing film MF is hardened more than the other portions.

The first processing gas may include a fluorine-containing gas. In an example, the fluorine-containing gas may be at least one selected from the group consisting of fluorocarbon gas, hydrofluorocarbon gas, NF₃ gas, and SF₆ gas. In an example, the fluorocarbon gas may be at least one selected from the group consisting of CF₄ gas, C₂F₂ gas, C₂F₄ gas, C₃F₆ gas, C₃F₈ gas, C₄F₆ gas, C₄F₈ gas, and C₅F₈ gas. In an example, the hydrofluorocarbon gas may be at least one selected from the group consisting of CHF₃ gas, CH₂F₂ gas, CH₃F gas, C₂HF₅ gas, C₂H₂F₄ gas, C₂H₃F₃ gas, C₂H₄F₂ gas, C₃HF₇ gas, C₃H₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas.

The first processing gas may include an oxygen-containing gas instead of the fluorine-containing gas. In an example, the oxygen-containing gas may be at least one selected from the group consisting of O₂ gas, CO gas, and CO₂ gas. In a case where the first processing gas includes the oxygen-containing gas, the first processing gas may further include a chlorine-containing gas. In an example, the chlorine-containing gas may be at least one selected from the group consisting of HCl gas, Cl₂ gas, BCl₃ gas, and SiCl₄ gas.

The first processing gas may further include an inert gas such as noble gas or N₂ gas.

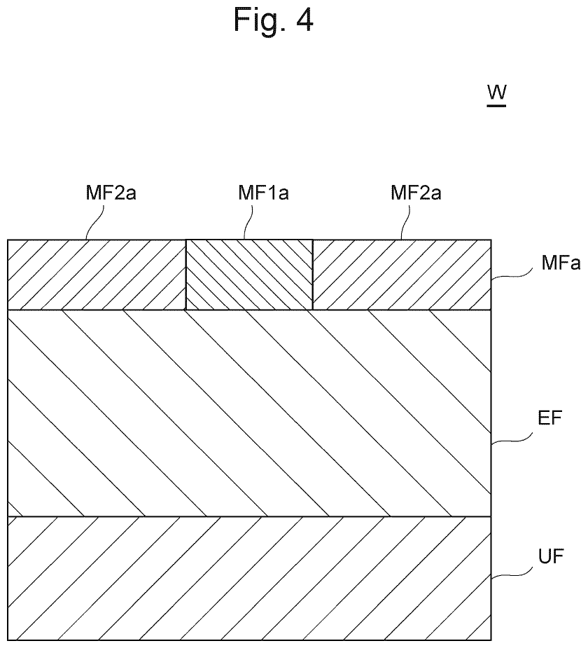

FIG. 4 is a diagram illustrating an example of a cross-sectional structure of the substrate W after the process in Step ST2. In FIG. 4, the reformed metal-containing film MF is illustrated as a metal-containing film MFa (MF1a and MF2a).

In a case where the first processing gas includes the fluorine-containing gas, the metal-containing film MFa may be fluorinated by the active species of fluorine in the first plasma. That is, a first region MF1a and a second region MF2a after the reforming process may have a high fluorine content compared to the first region MF1 and the second region MF2 before the reforming process. As a result, the content ratio of the other components (for example, oxygen, carbon, tin, or the like) contained before the reforming process may be reduced. A surface of the first region MF1a after the reforming process may be hard compared to a surface of the second region MF2a.

In a case where the first processing gas includes the oxygen-containing gas, the metal-containing film MFa may be oxidized by the active species of oxygen in the first plasma. The first region MF1a and the second region MF2a after the reforming process may have a high oxygen content compared to the first region MF1 and the second region MF2 before the reforming process. As a result, the content ratio of the other components (for example, carbon, tin, or the like) contained before the reforming process may be reduced. The surface of the first region MF1a after the reforming process may be hard compared to the surface of the second region MF2a.

As described above, the metal-containing film MF before the reforming process is a “negative” film. That is, the etching resistance of the first region MF1 to the plasma used in the development process is higher than the etching resistance of the second region MF2. In contrast, the metal-containing film MFa after the reforming process is a “positive” film. That is, the etching resistance of the second region MF2a is higher than the etching resistance of the first region MF1a. Therefore, for example, in a case where the reformed metal-containing film MFa is exposed to the second plasma used in the development process in Step ST3, the first region MF1a is selectively etched and removed with respect to the second region MF2a.

### (Step ST3: Development of Metal-Containing Film)

In Step ST3, the metal-containing film MFa is developed. First, a second processing gas is supplied from the gas supply 30 into the plasma processing chamber 10s. Then, the microwave is radiated from the microwave plasma source 20 into the plasma processing chamber 10s. As a result, a second plasma is formed from the second processing gas. In this case, a bias signal may be supplied to a lower electrode of the substrate support 11 to generate a bias potential between the second plasma and the substrate W. Ions and active species, such as radicals, in the second plasma are attracted to the substrate W, and the development process of the metal-containing film MFa proceeds by the active species.

The second processing gas may be selected corresponding to the first processing gas. In a case where the first processing gas includes the fluorine-containing gas, the second processing gas includes the chlorine-containing gas. The chlorine-containing gas may be, for example, BCl₃ gas or Cl₂ gas.

In a case where the first processing gas includes an oxygen gas, the second processing gas may include a hydrogen-containing gas (for example, H₂ gas), a nitrogen-containing gas (for example, N₂ gas), and a chlorine-containing gas (for example, Cl₂ gas). These gases may not be supplied at the same time. For example, the hydrogen-containing gas and the nitrogen-containing gas, and the chlorine-containing gas may be alternately supplied as the second processing gas. That is, a step of supplying the hydrogen-containing gas and the nitrogen-containing gas as the second processing gas to form the second plasma and a step of supplying the chlorine-containing gas as the second processing gas to form the second plasma may be alternately repeated.

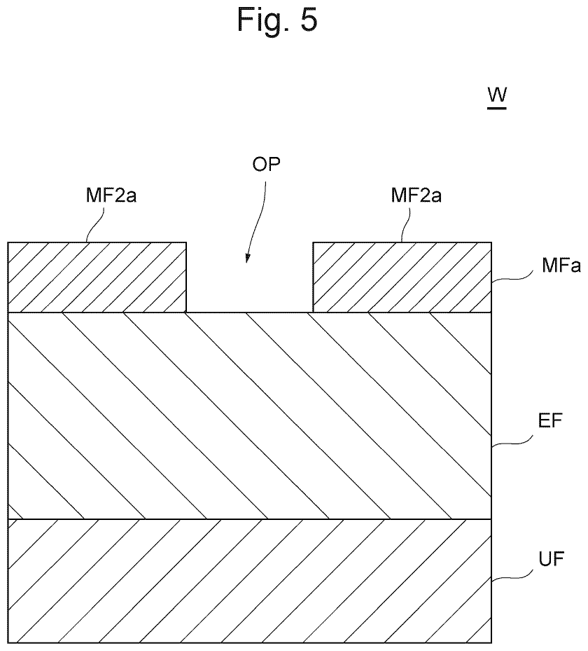

FIG. 5 is a diagram illustrating an example of a cross-sectional structure of the substrate W after the process in Step ST3. As described above, the etching resistance of the second region MF2a to the second plasma used in the development process is higher than the etching resistance of the first region MF1a. Therefore, as illustrated in FIG. 5, the first region MF1a is selectively etched and removed with respect to the second region MF2a by the development process. As a result, an opening OP is formed in the metal-containing film MFa.

The opening OP is defined by a side surface of the second region MF2a. The opening OP is a space on the film EF to be etched which is surrounded by the side surface. The opening OP has a shape corresponding to the first region MF1a in a plan view of the substrate W (consequently, a shape corresponding to the opening of the exposure mask used to expose the metal-containing film MF). The shape may be, for example, a circle, an ellipse, a rectangle, a line, or a shape obtained by combining one or more of these shapes. A plurality of openings OP may be formed in the metal-containing film MFa. The plurality of openings OP may have a hole shape and may be arranged at regular intervals to form an array pattern. In addition, the plurality of openings OP may have a linear shape and may be arranged at regular intervals to form a line-and-space pattern.

### (Step ST4: Etching of Etching Target Film)

In Step ST4, the film EF to be etched is etched. First, a third processing gas is supplied from the gas supply 30 into the plasma processing chamber 10s. The third processing gas may be selected such that the film EF to be etched can be etched with a sufficient selectivity with respect to the metal-containing film MFa. Then, the microwave is radiated from the microwave plasma source 20 into the plasma processing chamber 10s. As a result, a third plasma is formed from the third processing gas. In this case, a bias signal may be supplied to the lower electrode of the substrate support 11 to generate a bias potential between the third plasma and the substrate W. Ions and active species, such as radicals, in the third plasma are attracted to the substrate W, and the film EF to be is etched by the active species.

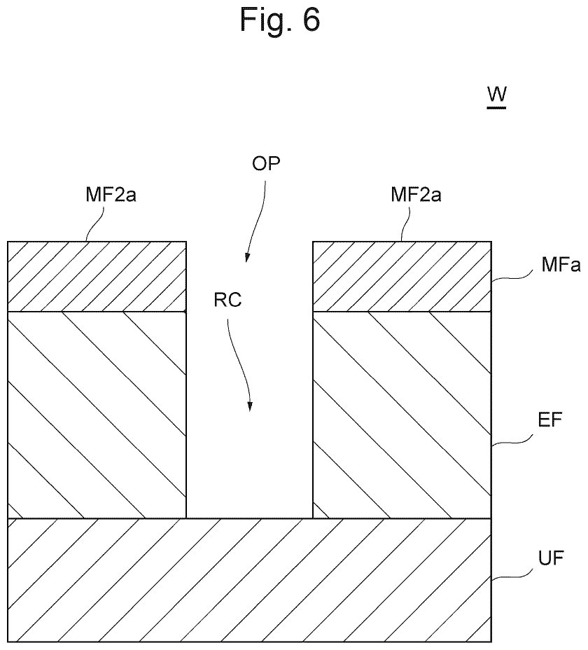

FIG. 6 is a diagram illustrating an example of a cross-sectional structure of the substrate W after the process in Step ST4. In Step ST4, the metal-containing film MFa functions as a mask, and the film EF to be etched is etched. As illustrated in FIG. 6, in Step ST4, a recessed portion RC is formed in the film EF to be etched based on the shape of the opening OP of the metal-containing film MFa.

According to the present processing method, the “negative” metal-containing film MF can be converted into a “positive” film by the reforming process. Therefore, a pattern including the unexposed second region MF2a can be formed in the metal-containing film MF by the development process. As a result, according to the present processing method, a fine pattern (for example, a fine hole array pattern) that is difficult to achieve with a normal “negative” photoresist film may be formed in the metal-containing film MF.

### EXAMPLES

Next, examples of the present processing method will be described. The present disclosure is not limited in any way by the following examples.

### Example 1

In Example 1, the present processing method was applied to the substrate W using the plasma processing apparatus 1. The metal-containing film MF on the substrate W was formed by exposing a photoresist film containing tin to EUV. The first processing gas used in the reforming process of Step ST2 included CF₄ gas. The second processing gas used in the development process of Step ST3 included BCl₃ gas and Cl₂ gas.

### Reference Example 1

In Reference Example 1, the development process was performed on the same metal-containing film MF as in Example 1 under the same conditions as in Step ST3 of Example 1 without performing the reforming process in Step ST2.

Table 1 illustrates the etching rates of the metal-containing films MF according to Example 1 and Reference Example 1 in the development process. “ER1” is an etching rate of the exposed first region. “ER2” is an etching rate of the unexposed second region.

TABLE 1

| | Example 1 | Reference Example 1 |
|---|---|---|
| ER1 [nm/min] | 116 | 159 |
| ER2 [nm/min] | 43 | 226 |

As illustrated in Table 1, in Example 1, the etching rate of the first region in the development process is higher than the etching rate of the second region. That is, the etching resistance of the second region to the plasma used in the development process was higher than the etching resistance of the first region. In contrast, in Reference Example 1, the etching rate of the second region in the development process is higher than the etching rate of the first region. That is, the etching resistance of the first region to the plasma used in the development process was higher than the etching resistance of the second region.

### Example 2

In Example 2, the present processing method was applied to the substrate W using the plasma processing apparatus 1. The metal-containing film MF was formed on the substrate W in the same manner as in Example 1. The first processing gas used in the reforming process of Step ST2 included Cl₂ gas and O₂ gas. In the development process of Step ST3, N₂ gas and H₂ gas, and Cl₂ gas were alternately supplied as the second processing gas.

### Reference Example 2

In Reference Example 2, the development process was performed on the same metal-containing film MF as in Example 2 under the same conditions as in Step ST3 of Example 2 without performing the reforming process in Step ST2.

Table 2 illustrates the etching rates of the metal-containing films MF according to Example 2 and Reference Example 2 in the development process. “ER1” is an etching rate of the exposed first region. “ER2” is an etching rate of the unexposed second region.

TABLE 2

| | Example 2 | Reference Example 2 |
|---|---|---|
| ER1 [nm/min] | 81 | 150 |
| ER2 [nm/min] | 37 | 219 |

As illustrated in Table 2, in Example 2, the etching rate of the first region in the development process is higher than the etching rate of the second region. That is, the etching resistance of the second region to the plasma used in the development process was higher than the etching resistance of the first region. In contrast, in Reference Example 2, the etching rate of the second region in the development process is higher than the etching rate of the first region. That is, the etching resistance of the first region to the plasma used in the development process was higher than the etching resistance of the second region.

The present processing method may be modified in various ways without departing from the scope and gist of the present disclosure. For example, the present processing method may be executed using a substrate processing apparatus using any plasma source, such as an inductively coupled plasma processing apparatus or a capacitively coupled plasma processing apparatus, in addition to the plasma processing apparatus 1 using the microwave plasma source.

According to an exemplary embodiment of the present disclosure, it is possible to provide a plasma processing method capable of forming a fine pattern in a metal-containing film.

The embodiments of the present disclosure further include the following aspects.

### (Addendum 1)

A plasma processing method performed with a plasma processing apparatus including a chamber, comprising:
(a) preparing a substrate on a substrate support in the chamber, the substrate including an etching target film and a metal-containing film provided on the etching target film, the metal-containing film including an exposed first region and an unexposed second region;
(b) reforming the metal-containing film using a first plasma formed from a first processing gas, the first processing gas including either a fluorine-containing gas or an oxygen-containing gas; and
(c) selectively removing the first region of the reformed metal-containing film with respect to the second region using a second plasma formed from a second processing gas.

### (Addendum 2)

The plasma processing method according to Addendum 1, in which, by the reforming in (b), etching resistance of the second region to the second plasma is higher than etching resistance of the first region to the second plasma.

### (Addendum 3)

The plasma processing method according to Addendum 1 or 2, in which (c) includes removing the first region such that the etching target film is exposed.

### (Addendum 4)

The plasma processing method according to any one of Addenda 1 to 3, in which the metal-containing film includes tin or titanium.

### (Addendum 5)

The plasma processing method according to Addendum 4, in which the metal-containing film includes an organic substance.

### (Addendum 6)

The plasma processing method according to any one of Addenda 1 to 5, in which the first processing gas includes at least one selected from the group consisting of fluorocarbon gas, hydrofluorocarbon gas, NF₃ gas, and SF₆ gas.

### (Addendum 7)

The plasma processing method according to Addendum 6, in which the second processing gas includes a chlorine-containing gas.

### (Addendum 8)

The plasma processing method according to Addendum 7, in which the chlorine-containing gas is BCI₃ gas or Cl₂ gas.

### (Addendum 9)

The plasma processing method according to any one of Addenda 1 to 5, in which the first processing gas includes at least one selected from the group consisting of O₂ gas, CO gas, and CO₂ gas.

### (Addendum 10)

The plasma processing method according to Addendum 9, in which the first processing gas further includes a chlorine-containing gas.

### (Addendum 11)

The plasma processing method according to Addendum 10, in which the chlorine-containing gas is at least one selected from the group consisting of Cl₂ gas, BCl₃ gas, and SiCl₄ gas.

### (Addendum 12)

The plasma processing method according to any one of Addenda 9 to 11, in which (c) includes alternately repeating (i) formation of the second plasma using a gas including a hydrogen-containing gas and a nitrogen-containing gas as the second processing gas and (ii) formation of the second plasma using a gas including a chlorine-containing gas as the second processing gas.

### (Addendum 13)

The plasma processing method according to any one of Addenda 1 to 12, in which the etching target film is a Si-containing film or a carbon-containing film.

### (Addendum 14)

The plasma processing method according to any one of Addenda 1 to 13, further including: (d) etching the etching target film, using the metal-containing film as a mask, after (c).

### (Addendum 15)

The plasma processing method according to Addendum 14, in which the steps (a) to (d) are performed in the same chamber.

### (Addendum 16)

The plasma processing method according to any one of Addenda 1 to 15, in which the metal-containing film includes a metal-containing photoresist film, the first region is an exposed region of the metal-containing photoresist film, and the second region is an unexposed region of the metal-containing photoresist film.

### (Addendum 17)

The plasma processing method according to Addendum 16, in which the first region is exposed to EUV.

### (Addendum 18)

A plasma processing system including: a chamber; a substrate support configured to be disposed in the chamber; and a controller, in which the controller is configured to cause:
(a) preparing a substrate on a substrate support in the chamber, the substrate including an etching target film and a metal-containing film provided on the etching target film, the metal-containing film including an exposed first region and an unexposed second region;
(b) reforming the metal-containing film using a first plasma formed from a first processing gas, the first processing gas including either a fluorine-containing gas or an oxygen-containing gas; and
(c) selectively removing the first region of the reformed metal-containing film with respect to the second region using a second plasma formed from a second processing gas.

### (Addendum 19)

A device manufacturing method performed with a plasma processing apparatus including a chamber, the method including:
(a) preparing a substrate on a substrate support in the chamber, the substrate including an etching target film and a metal-containing film provided on the etching target film, the metal-containing film including an exposed first region and an unexposed second region;
(b) reforming the metal-containing film using a first plasma formed from a first processing gas, the first processing gas including either a fluorine-containing gas or an oxygen-containing gas; and
(c) selectively removing the first region of the reformed metal-containing film with respect to the second region using a second plasma formed from a second processing gas.

### (Addendum 20)

A program causing a computer of a plasma processing system including a chamber and a substrate support provided in the chamber to execute:
(a) preparing a substrate on the substrate support, the substrate including an etching target film and a metal-containing film provided on the etching target film, the metal-containing film including an exposed first region and an unexposed second region;
(b) reforming the metal-containing film using a first plasma formed from a first processing gas, the first processing gas including either a fluorine-containing gas or an oxygen-containing gas; and
(c) selectively removing the first region of the reformed metal-containing film with respect to the second region using a second plasma formed from a second processing gas.

### (Addendum 21)

A storage medium storing the program according to Addendum 20.

What is claimed is:

1. A plasma processing method performed with a plasma processing apparatus including a chamber, comprising:
(a) preparing a substrate on a substrate support in the chamber, the substrate including an etching target film and a metal-containing film provided on the etching target film, the metal-containing film including an exposed first region and an unexposed second region;
(b) reforming the metal-containing film using a first plasma formed from a first processing gas, the first processing gas including either a fluorine-containing gas or an oxygen-containing gas; and
(c) selectively removing the first region of the reformed metal-containing film with respect to the second region using a second plasma formed from a second processing gas.

2. The plasma processing method according to claim 1,
wherein, by the reforming in (b), etching resistance of the second region to the second plasma is higher than etching resistance of the first region to the second plasma.

3. The plasma processing method according to claim 2,
wherein (c) includes removing the first region such that the etching target film is exposed.

4. The plasma processing method according to claim 1,
wherein the metal-containing film includes tin or titanium.

5. The plasma processing method according to claim 4,
wherein the metal-containing film includes an organic substance.

6. The plasma processing method according to claim 1,
wherein the first processing gas includes at least one selected from the group consisting of fluorocarbon gas, hydrofluorocarbon gas, NF₃ gas, and SF₆ gas.

7. The plasma processing method according to claim 6,
wherein the second processing gas includes a chlorine-containing gas.

8. The plasma processing method according to claim 7,
wherein the chlorine-containing gas is BCl₃ gas or Cl₂ gas.

9. The plasma processing method according to claim 1,
wherein the first processing gas includes at least one selected from the group consisting of O₂ gas, CO gas, and CO₂ gas.

10. The plasma processing method according to claim 9,
wherein the first processing gas further includes a chlorine-containing gas.

11. The plasma processing method according to claim 10,
wherein the chlorine-containing gas is at least one selected from the group consisting of Cl₂ gas, BCl₃ gas, and SiCl₄ gas.

12. The plasma processing method according to claim 9,
wherein (c) includes alternately repeating (i) formation of the second plasma using a gas including a hydrogen-containing gas and a nitrogen-containing gas as the second processing gas and (ii) formation of the second plasma using a gas including a chlorine-containing gas as the second processing gas.

13. The plasma processing method according to claim 1,
wherein the etching target film is a Si-containing film or a carbon-containing film.

14. The plasma processing method according to claim 1, further comprising:
(d) etching the etching target film, using the metal-containing film as a mask, after (c).

15. The plasma processing method according to claim 14,
wherein (a) to (d) are performed in the same chamber.

16. The plasma processing method according to claim 1,
wherein the metal-containing film includes a metal-containing photoresist film, the first region is an exposed region of the metal-containing photoresist film, and
the second region is an unexposed region of the metal-containing photoresist film.

17. The plasma processing method according to claim 16,
wherein the first region is exposed to EUV.

18. A plasma processing system comprising:
a chamber;
a substrate support configured to be disposed in the chamber; and
a controller,
wherein the controller is configured to cause:
(a) preparing a substrate on a substrate support in the chamber, the substrate including an etching target film and a metal-containing film provided on the etching target film, the metal-containing film including an exposed first region and an unexposed second region;
(b) reforming the metal-containing film using a first plasma formed from a first processing gas, the first processing gas including either a fluorine-containing gas or an oxygen-containing gas; and
(c) selectively removing the first region of the reformed metal-containing film with respect to the second region using a second plasma formed from a second processing gas.
